(19) United States
(12) Patent Application Publication
(10) Pub. No.: US 2016/0308070 A1
(43) Pub. Date: Oct. 20, 2016

(54) SEMICONDUCTOR DEVICE

(71) Applicant: National Chiao Tung University, Hsinchu City (TW)

(72) Inventors: Chun-Yen Chang, Hsinchu County (TW); Chun-Hu Cheng, Tainan City (TW); Yu-Chien Chiu, Kaohsiung City (TW)

(21) Appl. No.: 15/051,679

(22) Filed: Feb. 24, 2016

(30) Foreign Application Priority Data
Apr. 14, 2015 (TW) 104111969

(51) Int. Cl. H01L 29/792; H01L 29/51; H01L 29/49; H01L 29/78; H01L 29/423

(52) U.S. Cl. CPC H01L 29/792; H01L 29/78391; H01L 29/42348; H01L 29/495; H01L 29/4966; H01L 29/516; H01L 29/517; H01L 29/518; H01L 29/513

(57) ABSTRACT

The invention provides a semiconductor device including a substrate, a first dielectric layer, a conductive layer, a ferroelectric material layer, and a charge-trapping layer. The first dielectric layer is disposed on the substrate. The conductive layer is disposed on the first dielectric layer. The ferroelectric material layer and the charge-trapping layer are disposed between the first dielectric layer and the conductive layer by stacking. The semiconductor device of the invention has better memory characteristics and transistor characteristics.

### CROSS-REFERENCE TO RELATED APPLICATION

This application claims the priority benefit of Taiwan application serial no. 104111969, filed on Apr. 14, 2015. The entirety of the above-mentioned patent application is hereby incorporated by reference herein and made a part of this specification.

### BACKGROUND OF THE INVENTION

1. Field of the Invention

The invention relates to a semiconductor device. More particularly, the invention relates to a semiconductor device having memory characteristics and transistor characteristics.

2. Description of Related Art

Even though existing flash memory has low Pico-Joule switching power consumption, the flash memory also has unacceptable drawbacks of large operation voltage and slow operation speed (ms-grade) and the phenomenon of poor endurance at a reduced size of 20 nm or less (such as an endurance of about 104 read and write operations).

In recent years, a hafnium oxide-type (HfZrO or HfSiO) ferroelectric non-volatile transistor (FeNVM) and a process technique in which a high-k/metal gate (HK/MG) is used have been developed. However, a single layer hafnium oxide-based ferroelectric thin film cannot prevent issues such as endurance attenuation under prolonged reading and writing and drifting or reduction of memory operation interval (ΔV_{T} (threshold voltage difference)) of threshold voltage. The reason is, when a device is reduced to nano-size, polarization relaxation caused by depolarization field characteristics becomes more apparent, thus significantly affecting memory characteristics.

### SUMMARY OF THE INVENTION

The invention provides a semiconductor device having better memory characteristics and transistor characteristics.

The invention provides a semiconductor device including a substrate, a first dielectric layer, a conductive layer, a ferroelectric material layer, and a charge-trapping layer. The first dielectric layer is disposed on the substrate. The conductive layer is disposed on the first dielectric layer. The ferroelectric material layer and the charge-trapping layer are disposed between the first dielectric layer and the conductive layer by stacking.

According to an embodiment of the invention, in the semiconductor device, the substrate can be a planar semiconductor substrate or a three-dimensional semiconductor substrate with fin-designed structure.

According to an embodiment of the invention, in the semiconductor device, the substrate is, for instance, a tetravalent semiconductor substrate, a Group III-V semiconductor substrate, or a Group II-VI semiconductor substrate.

According to an embodiment of the invention, in the semiconductor device, the material of the first dielectric layer is, for instance, an oxide.

According to an embodiment of the invention, in the semiconductor device, the material of the conductive layer is, for instance, a metal integrated with a strain function or doped polysilicon.

According to an embodiment of the invention, in the semiconductor device, the strain function of the metal can be adjusted by the number of layers of the metal, a compound ratio of the metal or a combination thereof.

According to an embodiment of the invention, in the semiconductor device, the metal is, for instance, Ti, Al, Zr, Hf, V, Ta, Nb, Cr, Mo, W, Co, TiN, TiC, TiAlC, TaC, TaAlC, NbAlC, TiAl, TaAl, TaN, TaCN, WN, TiWN or a combination thereof.

According to an embodiment of the invention, in the semiconductor device, the ferroelectric material layer is, for instance, disposed between the first dielectric layer and the charge-trapping layer.

According to an embodiment of the invention, in the semiconductor device, the charge-trapping layer is, for instance, disposed between the first dielectric layer and the ferroelectric material layer.

According to an embodiment of the invention, in the semiconductor device, the ferroelectric material layer can have ferroelectric characteristics and anti-ferroelectric characteristics to obtain negative capacitance characteristics.

According to an embodiment of the invention, in the semiconductor device, the material of the ferroelectric material layer is, for instance, hafnium zirconium oxide (HfZrO), hafnium silicon oxide (HfSiO), lead zirconate titanate (PZT), barium strontium titanate (BST), strontium bismuth tantalate (SBT), lead lanthanum zirconate titanate (PLZT), hafnium aluminum oxide (HfAlO), hafnium yttrium oxide (HfYO), LiNbO₃, BaMgF, BaMnF, BaFeF, BaCoF, BaNiF, BaZnF, SrAlF₅, PVDF, PVDF-TrEE, La₁₋ₓSrₓMnO₃ or HfO₂ doped with Sr, Y, Zr, La, Nd, Sm or Gd.

According to an embodiment of the invention, in the semiconductor device, the material of the charge-trapping layer is, for instance, a conductive material, a semiconductor material, a dielectric material, graphene, or a nanodot.

According to an embodiment of the invention, in the semiconductor device, the dielectric material is, for instance, a high-k material. The high-k material is, for instance, zirconium silicon oxide (ZrSiO), silicon nitride, tantalum oxide, silicon oxynitride, barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide, or aluminum oxide.

According to an embodiment of the invention, in the semiconductor device, the nanodot is, for instance, a semiconductor nanodot or a metal nanodot. The semiconductor nanodot is, for instance, a silicon nanodot or a germanium nanodot. The metal nanodot is, for instance, a gold nanodot or a silver nanodot.

According to an embodiment of the invention, in the semiconductor device, a second dielectric layer is further included. The second dielectric layer is disposed between a composite layer of the ferroelectric material layer and the charge-trapping layer and the conductive layer.

According to an embodiment of the invention, in the semiconductor device, the material of the second dielectric layer is, for instance, an oxide.

According to an embodiment of the invention, in the semiconductor device, a first doped region and a second doped region are further included. The first doped region and the second doped region are respectively disposed in the substrate at one side of and another side of the conductive layer.

According to an embodiment of the invention, in the semiconductor device, the semiconductor device can be a memory device or a field-effect transistor (FET) device.

According to an embodiment of the invention, in the semiconductor device, the memory device is, for instance, a static random access memory (SRAM), a dynamic random access memory (DRAM), or a non-volatile memory (NVM).

The invention provides another semiconductor device including a substrate, a charge-trapping layer, a first conductive layer, a ferroelectric material layer, and a second conductive layer. The charge-trapping layer is disposed on the substrate. The first conductive layer is disposed on the charge-trapping layer. The ferroelectric material layer is disposed on the first conductive layer. The second conductive layer is disposed on the ferroelectric material layer.

According to an embodiment of the invention, in the semiconductor device, a ferroelectric capacitor formed by the first conductive layer, the ferroelectric material layer, and the second conductive layer can have negative capacitance characteristics.

According to an embodiment of the invention, in the semiconductor device, a first dielectric layer is further included. The first dielectric layer is disposed between the substrate and the charge-trapping layer.

According to an embodiment of the invention, in the semiconductor device, a second dielectric layer is further included. The second dielectric layer is disposed between the first conductive layer and the ferroelectric material layer.

According to an embodiment of the invention, in the semiconductor device, a first doped region and a second doped region are further included. The first doped region and the second doped region are respectively disposed in the substrate at one side of and another side of the first conductive layer.

Based on the above, since the semiconductor devices provided in the invention adopt both the ferroelectric material layer and the charge-trapping layer, the semiconductor devices can contain both ferroelectric polarization characteristics and a charge-trapping mechanism, and therefore can have better memory characteristics and transistor characteristics.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a semiconductor device of an embodiment of the invention.

FIG. 2 shows a semiconductor device of another embodiment of the invention.

FIG. 3 is an I_{D} (drain current)-V_{G} (gate voltage) diagram of basic electrical properties of semiconductor devices respectively having a gate with weakly strain and a gate with strong strain.

FIG. 4 shows a semiconductor device of another embodiment of the invention.

FIG. 5 shows a semiconductor device of another embodiment of the invention.

FIG. 6 is a crystal structure diagram of a ferroelectric material layer (HfZrO) of an experimental example of the invention.

FIG. 7 is a polarization characteristics diagram of a ferroelectric material layer of an experimental example of the invention.

FIG. 8 is an I_{D}-V_{G} diagram of basic electrical properties of a semiconductor device of an experimental example of the invention.

FIG. 9 shows the relationship of subthreshold swing and gate voltage obtained from the I_{D}-V_{G} diagram of FIG. 8.

FIG. 10 shows the relationship of surface potential gain and gate voltage obtained from the I_{D}-V_{G} diagram of FIG. 8.

FIG. 11 shows the relationship of polarization characteristics (P) and energy (U) and dU/dP obtained from the I_{D}-V_{G} diagram of FIG. 8.

FIG. 12 is an endurance test diagram of a semiconductor device of an experimental example of the invention.

### DESCRIPTION OF THE EMBODIMENTS

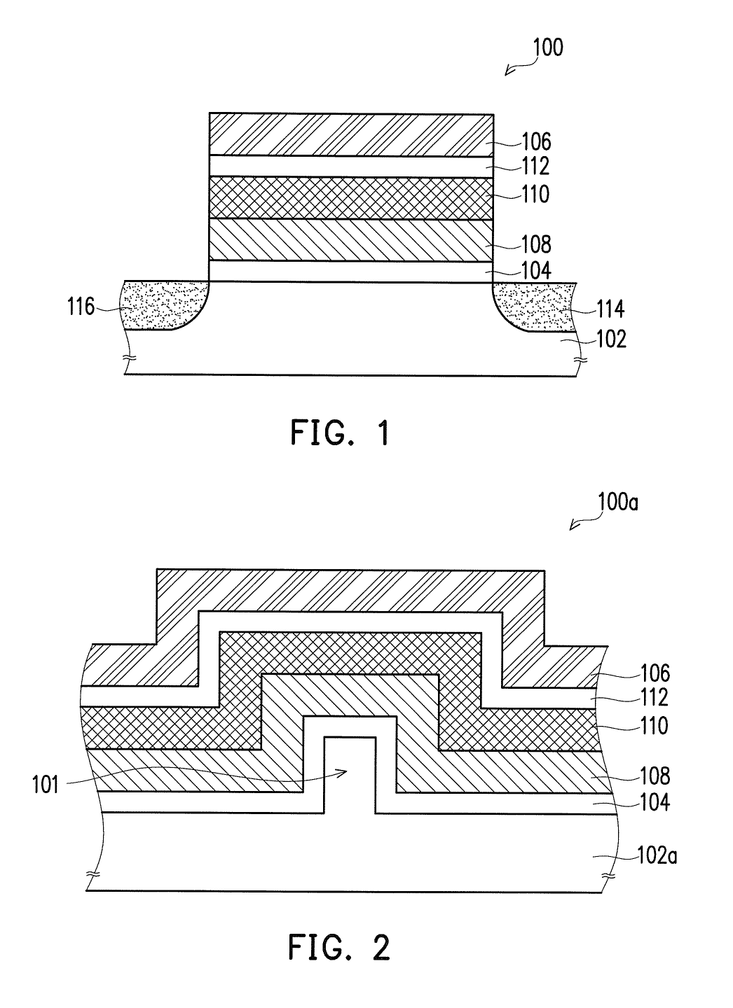

FIG. 1 shows a semiconductor device of an embodiment of the invention.

FIG. 2 shows a semiconductor device of another embodiment of the invention.

Referring to FIG. 1, a semiconductor device 100 includes a substrate 102, a dielectric layer 104, a conductive layer 106, a ferroelectric material layer 108, and a charge-trapping layer 110. The semiconductor device 100 can be a semiconductor device having memory characteristics and transistor characteristics, that is, the semiconductor device 100 can be used as a memory device or a field-effect transistor device. The memory device is, for instance, a static random access memory (SRAM), a dynamic random access memory (DRAM), or a non-volatile memory (NVM). Moreover, the semiconductor device 100 can be further applied in a three-dimensional high-density memory structure.

In the present embodiment, the substrate 102 is exemplified as a planar semiconductor substrate, but the invention is not limited thereto. In another embodiment, the substrate 102 can also be a three-dimensional semiconductor substrate with fin-designed structure. For instance, referring to FIG. 2, a substrate 102a of a semiconductor device 100a can have a fin structure 101. In this case, the semiconductor device 100a can be a fin-FET device. In the following, the semiconductor device of the present embodiment is further described with reference to FIG. 1. The disposition method, the material, the forming method, and the efficacy of other components of the semiconductor device 100a of FIG. 2 and the semiconductor device 100 of FIG. 1 are similar, and therefore the components are represented by the same reference numerals as shown below.

The substrate 102 is, for instance, a semiconductor substrate such as a tetravalent semiconductor substrate, a Group III-V semiconductor substrate, or a Group II-VI semiconductor substrate. For instance, the semiconductor substrate can be a silicon substrate, a germanium substrate, or a silicon-germanium substrate. Moreover, the material of the semiconductor substrate can be a polycrystal or amorphous semiconductor material. Moreover, the substrate 102 can be a P-type substrate or an N-type substrate.

The dielectric layer 104 is disposed on the substrate 102. In the present embodiment, the dielectric layer 104 can be used as a buffer layer. In other embodiments, the dielectric layer 104 can also be used as a tunneling dielectric layer. The material of the dielectric layer 104 is, for instance, an oxide such as silicon oxide. The thickness of the dielectric layer 104 is, for instance, 0.1 nm to 10 nm. The forming method of the dielectric layer 104 is, for instance, a thermal oxidation method or a chemical vapor deposition method.

The conductive layer 106 is disposed on the dielectric layer 104 and can be used as a gate. The material of the conductive layer 106 is, for instance, a metal integrated with a strain function or doped polysilicon. The strain function of the metal can be adjusted by the number of layers of the metal, a compound ratio of the metal or a combination thereof. When the material of the conductive layer 106 is the metal integrated with the strain function, the conductive layer 106 can be used as a strained gate. The metal is, for instance, Ti, Al, Zr, Hf, V, Ta, Nb, Cr, Mo, W, Co, TiN, TiC, TiAlC, TaC, TaAlC, NbAlC, TiAl, TaAl, TaN, TaCN, WN, TiWN or a combination thereof. The thickness of the conductive layer 106 is, for instance, 10 nm to 400 nm. The forming method of the conductive layer 106 is, for instance, a physical vapor deposition method or a chemical vapor deposition method.

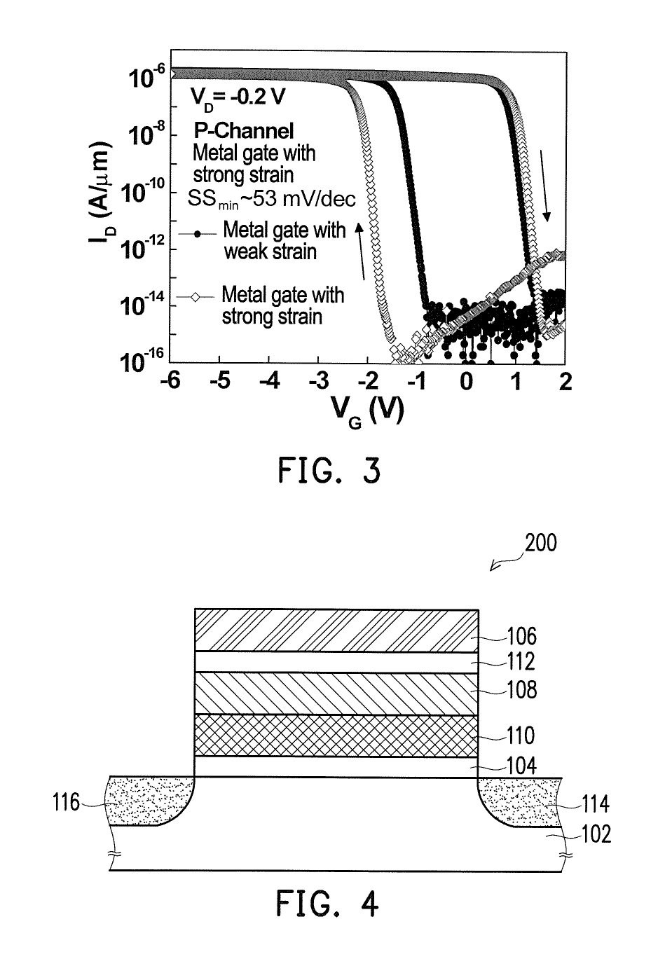

FIG. 3 is an I_{D} (drain current)-V_{G} (gate voltage) diagram of basic electrical properties of semiconductor devices respectively having a gate with weak strain and a gate with strong strain.

Referring to FIG. 3, compared with the semiconductor device having a gate with weak strain, the semiconductor device having a gate with strong strain can get a larger delta threshold voltage window (memory window) and subthreshold swing less than 60 mv/dec. Such feature will prove that the strain of the metal gate (strained gate) can improve the memory property and power efficiency.

The ferroelectric material layer 108 and the charge-trapping layer 110 are disposed between the dielectric layer 104 and the conductive layer 106 by stacking. The ferroelectric material layer 108 can have ferroelectric characteristics and anti-ferroelectric characteristics to obtain negative capacitance characteristics. In the present embodiment, the ferroelectric material layer 108 and the charge-trapping layer 110 are disposed in a manner in which the ferroelectric material layer 108 is disposed between the dielectric layer 104 and the charge-trapping layer 110 as an example, but the invention is not limited thereto. In another embodiment, the ferroelectric material layer 108 and the charge-trapping layer 110 can also be disposed in a manner in which the charge-trapping layer 110 is disposed between the dielectric layer 104 and the ferroelectric material layer 108.

The ferroelectric material layer 108 can be used to generate a polarized electric field. The material of the ferroelectric material layer 108 is, for instance, hafnium zirconium oxide, hafnium silicon oxide, lead zirconate titanate, barium strontium titanate, strontium bismuth tantalate, lead lanthanum zirconate titanate, hafnium aluminum oxide, hafnium yttrium oxide, LiNbO₃, BaMgF, BaMnF, BaFeF, BaCoF, BaNiF, BaZnF, SrAlF₅, PVDF, PVDF-TrEE, La₁₋ₓSrₓMnO₃ or HfO₂ doped with Sr, Y, Zr, La, Nd, Sm or Gd. The thickness of the ferroelectric material layer 108 is, for instance, 2 nm to 2 μm. The forming method of the ferroelectric material layer 108 is, for instance, a chemical vapor deposition method.

The charge-trapping layer 110 can be used to trap a charge therein. The material of the charge-trapping layer 110 is, for instance, a conductive material, a semiconductor material, a dielectric material, graphene, or a nanodot. The material of the dielectric material is, for instance, a high-k material. The high-k material is, for instance, zirconium silicon oxide, silicon nitride, tantalum oxide, silicon oxynitride, barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide, or aluminum oxide. The graphene can be porous graphene. The nanodot is, for instance, a semiconductor nanodot or a metal nanodot. The semiconductor nanodot is, for instance, a silicon nanodot or a germanium nanodot. The metal nanodot is, for instance, a gold nanodot or a silver nanodot. The thickness of the charge-trapping layer 110 is, for instance, 1 nm to 100 nm. The forming method of the charge-trapping layer 110 is, for instance, a chemical vapor deposition method.

Moreover, the semiconductor device 100 can further include a dielectric layer 112. The dielectric layer 112 is disposed between a composite layer of the ferroelectric material layer 108 and the charge-trapping layer 110 and the conductive layer 106. In the present embodiment, the dielectric layer 112 can be used as a tunneling dielectric layer. The material of the dielectric layer 112 is, for instance, an oxide such as silicon oxide. The thickness of the dielectric layer 112 is, for instance, 0.1 nm to 10 nm. The forming method of the dielectric layer 112 is, for instance, a chemical vapor deposition method.

Moreover, the semiconductor device 100 can further include a doped region 114 and a doped region 116. The doped region 114 and the doped region 116 are respectively disposed in the substrate 102 at one side of and another side of the conductive layer 106. The doped region 114 and the doped region 116 can be respectively used as a source and a drain. The conductivity types of the doped region 114 and the doped region 116 are different from the conductivity type of the substrate 102. For instance, when the substrate 102 is a P-type substrate, the doped region 114 and the doped region 116 are respectively N-type doped regions. When the substrate 102 is an N-type substrate, the doped region 114 and the doped region 116 are respectively P-type doped regions. The forming method of the doped region 114 and the doped region 116 is, for instance, an ion implantation method.

It can be known from the above embodiments that, since the semiconductor device 100 adopts both the ferroelectric material layer 108 and the charge-trapping layer 110, the semiconductor device 100 can contain both ferroelectric polarization characteristics and a charge-trapping mechanism, and therefore the semiconductor device 100 has the following preferred memory characteristics. In terms of the operating characteristics in the case that the semiconductor device 100 is used as a ferroelectric memory, the charge-trapping layer 110 can effectively increase the polarized electric field of the ferroelectric material layer 108, and thereby reduce the operating voltage of the ferroelectric memory. In terms of the operating characteristics in the case that the semiconductor device 100 is used as a charge-trapping memory, the polarized electric field of the ferroelectric material layer 108 can effectively increase the write speed and the erase speed of the charge-trapping memory.

Moreover, in comparison to a traditional ferroelectric memory, not only can the charge-trapping layer 110 of the semiconductor device 100 alleviate the phenomenon of temperature-dependent polarization relaxation, the charge-trapping layer 110 of the semiconductor device 100 can also improve high-temperature endurance reliability. Therefore, the semiconductor device 100 can further have lower subthreshold swing (such as reaching 60 mv/dec or less), lower leakage current (such as as low as 10⁻¹⁵ A/μm), greater memory operation interval (such as ΔV_{T} greater than 2V), faster read and write speed (such as 20 ns or less), and good endurance (such as more than 10¹² read/write (P/E) operations). As a result, after conditions are optimized, the semiconductor device 100 can be applied in a next-generation memory structure. Moreover, since the semiconductor device 100 can have lower operation voltage and fast read and write speed, and can reduce power consumption of device switching, the semiconductor device 100 can be further applied in a three-dimensional high-density memory.

Moreover, since the semiconductor device 100 adopts both the ferroelectric material layer 108 and the charge-trapping layer 110, the semiconductor device 100 can contain both ferroelectric polarization characteristics and a charge-trapping mechanism, and therefore the semiconductor device 100 has the following preferred transistor characteristics. That is, the semiconductor device 100 can have lower subthreshold swing (such as reaching 60 mv/dec or less) and lower leakage current (such as as low as 10⁻¹⁵ A/μm).

FIG. 4 shows a semiconductor device of another embodiment of the invention.

Referring to both FIG. 1 and FIG. 4, the difference between a semiconductor device 200 of FIG. 4 and the semiconductor device 100 of FIG. 1 is: the ferroelectric material layer 108 and the charge-trapping layer 110 are disposed in a different manner. In the semiconductor device 200, the ferroelectric material layer 108 and the charge-trapping layer 110 are disposed in a manner in which the charge-trapping layer 110 is disposed between the dielectric layer 104 and the ferroelectric material layer 108. Moreover, the disposition method, the material, the forming method, and the efficacy of other components of the semiconductor device 200 of FIG. 4 and the semiconductor device 100 of FIG. 1 are similar, so the components are therefore represented by the same reference numerals and are not repeated herein.

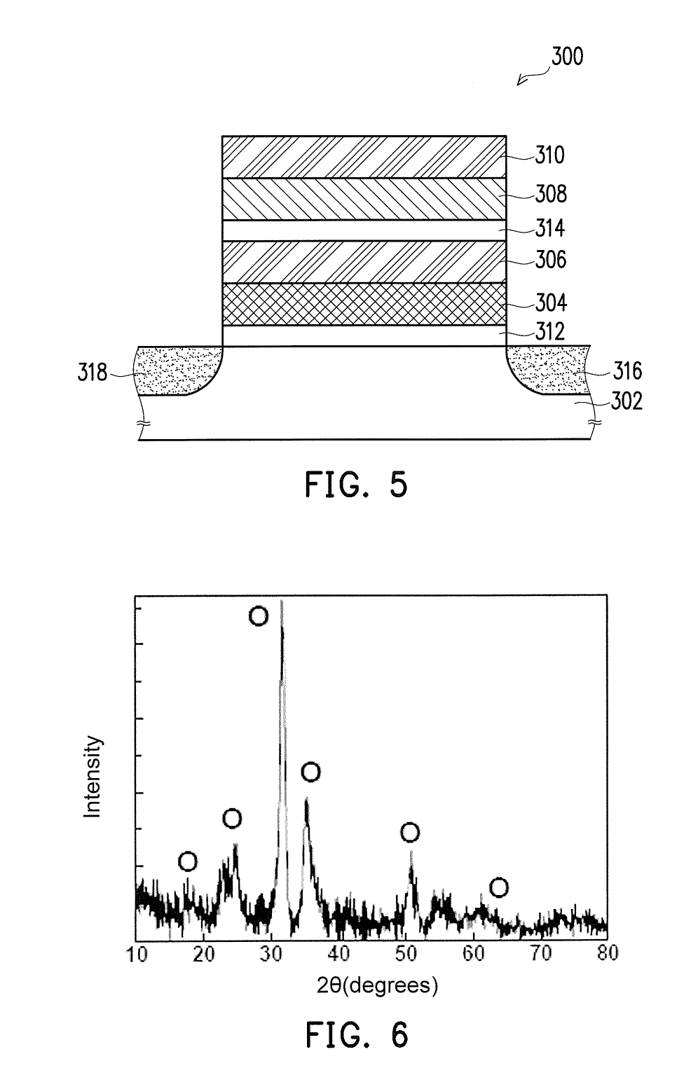

FIG. 5 shows a semiconductor device of another embodiment of the invention.

Referring to FIG. 5, a semiconductor device 300 includes a substrate 302, a charge-trapping layer 304, a conductive layer 306, a ferroelectric material layer 308, and a conductive layer 310. The semiconductor device 300 can be a semiconductor device having memory characteristics and transistor characteristics, that is, the semiconductor device 300 can be used as a memory device or a field-effect transistor device. The memory device is, for instance, a static random access memory (SRAM), a dynamic random access memory (DRAM), or a non-volatile memory (NVM). Moreover, the semiconductor device 300 can be further applied in a three-dimensional high-density memory structure.

In the present embodiment, the substrate 302 is exemplified as a planar semiconductor substrate, but the invention is not limited thereto. In another embodiment, the substrate 302 can also be a three-dimensional semiconductor substrate with fin-designed structure, and in this case, the semiconductor device 300 can be a fin-FET device. The substrate 302 is, for instance, a semiconductor substrate 302 such as a tetravalent semiconductor substrate, a Group III-V semiconductor substrate, or a Group II-VI semiconductor substrate. For instance, the semiconductor substrate can be a silicon substrate, a germanium substrate, or a silicon-germanium substrate. Moreover, the material of the semiconductor substrate can be a polycrystal or amorphous semiconductor material. Moreover, the substrate 302 can be a P-type substrate or an N-type substrate.

The charge-trapping layer 304 is disposed on the substrate 302. The charge-trapping layer 304 can be used to trap a charge therein. The material of the charge-trapping layer 304 is, for instance, a conductive material, a semiconductor material, a dielectric material, graphene, or a nanodot. The material of the dielectric material is, for instance, a high-k material. The high-k material is, for instance, zirconium silicon oxide, silicon nitride, tantalum oxide, silicon oxynitride, barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide, or aluminum oxide. The nanodot is, for instance, a semiconductor nanodot or a metal nanodot. The graphene can be porous graphene. The semiconductor nanodot is, for instance, a silicon nanodot or a germanium nanodot. The metal nanodot is, for instance, a gold nanodot or a silver nanodot. The thickness of the charge-trapping layer 304 is, for instance, 1 nm to 100 nm. The fanning method of the charge-trapping layer 304 is, for instance, a chemical vapor deposition method.

The conductive layer 306 is disposed on the charge-trapping layer 304. The material of the conductive layer 306 is, for instance, a metal integrated with a strain function or doped polysilicon. The strain function of the metal can be adjusted by the number of layers of the metal, a compound ratio of the metal or a combination thereof. When the material of the conductive layer 306 is the metal integrated with the strain function, the conductive layer 306 can be used as a strained gate. The metal is, for instance, Ti, Al, Zr, Hf, V, Ta, Nb, Cr, Mo, W, Co, TiN, TiC, TiAlC, TaC, TaAlC, NbAlC, TiAl, TaAl, TaN, TaCN, WN, TiWN or a combination thereof. The thickness of the conductive layer 306 is, for instance, 0.5 nm to 400 nm. The forming method of the conductive layer 306 is, for instance, a physical vapor deposition method or a chemical vapor deposition method.

The ferroelectric material layer 308 is disposed on the conductive layer 306. The ferroelectric material layer 308 can be used to generate a polarized electric field. The ferroelectric material layer 308 can have ferroelectric characteristics and anti-ferroelectric characteristics to obtain negative capacitance characteristics. The material of the ferroelectric material layer 308 is, for instance, hafnium zirconium oxide, hafnium silicon oxide, lead zirconate titanate, barium strontium titanate, strontium bismuth tantalate, lead lanthanum zirconate titanate, hafnium aluminum oxide, hafnium yttrium oxide, LiNbO₃, BaMgF, BaMnF, BaFeF, BaCoF, BaNiF, BaZnF, SrAlF₅, PVDF, PVDF-TrEE, La₁₋ₓSrₓMnO₃ or HfO₂ doped with Sr, Y, Zr, La, Nd, Sm or Gd. The thickness of the ferroelectric material layer 308 is, for instance, 2 nm to 2 μm. The forming method of the ferroelectric material layer 308 is, for instance, a chemical vapor deposition method.

The conductive layer 310 is disposed on the ferroelectric material layer 308. The material of the conductive layer 310 is, for instance, a metal integrated with a strain function or doped polysilicon. The strain function of the metal can be adjusted by the number of layers of the metal, a compound ratio of the metal or a combination thereof When the material of the conductive layer 310 is the metal integrated with the strain function, the conductive layer 310 can be used as a strained gate. The metal is, for instance, Ti, Al, Zr, Hf, V, Ta, Nb, Cr, Mo, W, Co, TiN, TiC, TiAlC, TaC, TaAlC, NbAlC, TiAl, TaAl, TaN, TaCN, WN, TiWN or a combination thereof The thickness of the conductive layer 310 is, for instance, 10 nm to 400 nm. The forming method of the conductive layer 310 is, for instance, a physical vapor deposition method or a chemical vapor deposition method.

In the present embodiment, the ferroelectric capacitor formed by the conductive layer 306, the ferroelectric material layer 308, and the conductive layer 310 can have negative capacitance characteristics.

Moreover, the semiconductor device 300 can further include a dielectric layer 312. The dielectric layer 312 is disposed between the substrate 302 and the charge-trapping layer 304. In the present embodiment, the dielectric layer 312 can be used as a buffer layer. The material of the dielectric layer 312 is, for instance, an oxide such as silicon oxide. The thickness of the dielectric layer 312 is, for instance, 0.1 nm to 10 nm. The forming method of the dielectric layer 312 is, for instance, a thermal oxidation method or a chemical vapor deposition method.

Moreover, the semiconductor device 300 can further include a dielectric layer 314. The dielectric layer 314 is disposed between the conductive layer 306 and the ferroelectric material layer 308. The ferroelectric capacitor formed by the conductive layer 306, the dielectric layer 314, the ferroelectric material layer 308, and the conductive layer 310 can have negative capacitance characteristics. The material of the dielectric layer 314 is, for instance, an oxide such as silicon oxide. The thickness of the dielectric layer 314 is, for instance, 0.1 nm to 10 nm. The forming method of the dielectric layer 314 is, for instance, a chemical vapor deposition method.

Moreover, the semiconductor device 300 can further include a doped region 316 and a doped region 318. The doped region 316 and the doped region 318 are respectively disposed in the substrate 302 at one side of and another side of the conductive layer 306. The doped region 316 and the doped region 318 can be respectively used as a source and a drain. The conductivity types of the doped region 316 and the doped region 318 are different from the conductivity type of the substrate 302. For instance, when the substrate 302 is a P-type substrate, the doped region 316 and the doped region 318 are respectively N-type doped regions. When the substrate 302 is an N-type substrate, the doped region 316 and the doped region 318 are respectively P-type doped regions. The forming method of the doped region 316 and the doped region 318 is, for instance, an ion implantation method.

It can be known from the above embodiments that, since the semiconductor device 300 adopts both the ferroelectric material layer 308 and the charge-trapping layer 304, the semiconductor device 300 can contain both ferroelectric polarization characteristics and a charge-trapping mechanism, and therefore the semiconductor device 300 has the following preferred memory characteristics. In terms of the operating characteristics in the case that the semiconductor device 300 is used as a ferroelectric memory, the charge-trapping layer 304 can effectively increase the polarized electric field of the ferroelectric material layer 308, and thereby reduce the operating voltage of the ferroelectric memory. In terms of the operating characteristics in the case that the semiconductor device 300 is used as a charge-trapping memory, the polarized electric field of the ferroelectric material layer 308 can effectively increase the write speed and the erase speed of the charge-trapping memory.

Moreover, in comparison to a traditional ferroelectric memory, not only can the charge-trapping layer 304 of the semiconductor device 300 alleviate the phenomenon of temperature-dependent polarization relaxation, the charge-trapping layer 304 of the semiconductor device 300 can also improve high-temperature endurance reliability. Therefore, the semiconductor device 300 can further have lower subthreshold swing, lower leakage current, greater memory operation interval, faster read and write speed, and good endurance. As a result, after conditions are optimized, the semiconductor device 300 can be applied in a next-generation semiconductor device. Moreover, since the semiconductor device 300 can have lower operation voltage and fast read and write speed, and can reduce power consumption of device switching, the semiconductor device 300 can be further applied in a three-dimensional high-density memory.

Moreover, since the semiconductor device 300 adopts both the ferroelectric material layer 308 and the charge-trapping layer 304, the semiconductor device 300 can contain both ferroelectric polarization characteristics and a charge-trapping mechanism, and therefore the semiconductor device 300 has the following preferred transistor characteristics. That is, the semiconductor device 300 can have lower subthreshold swing and lower leakage current.

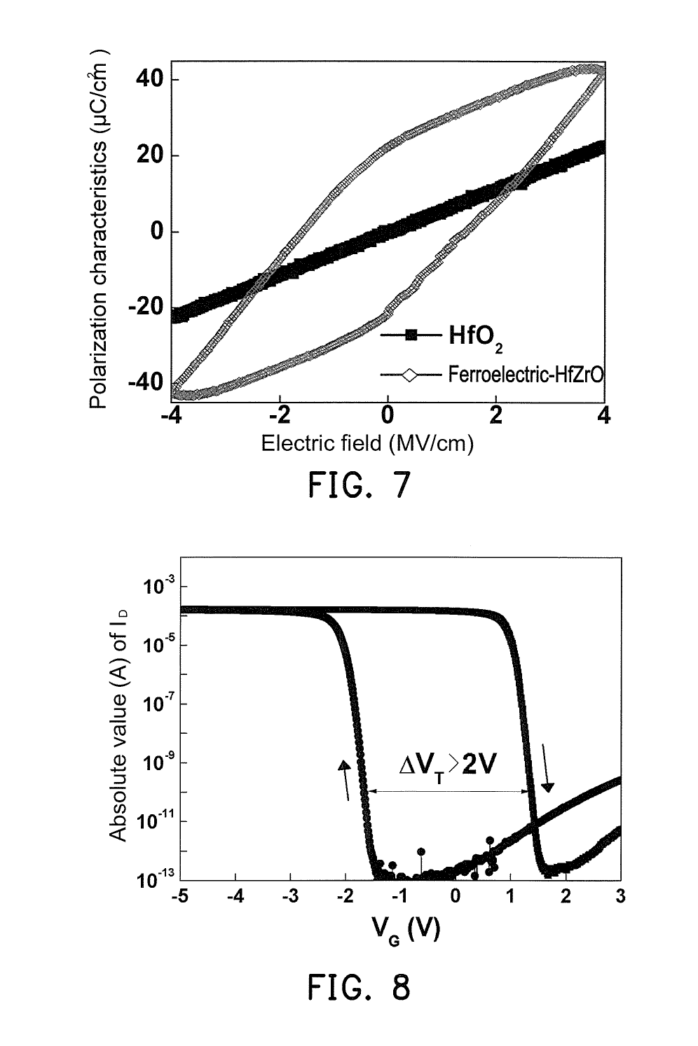

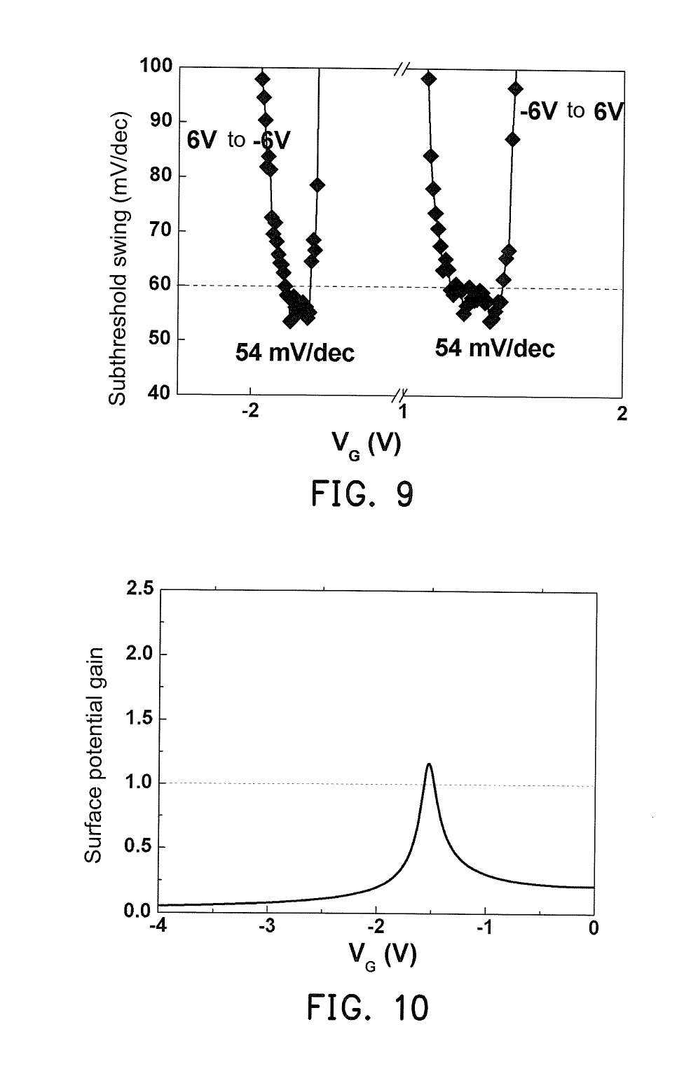

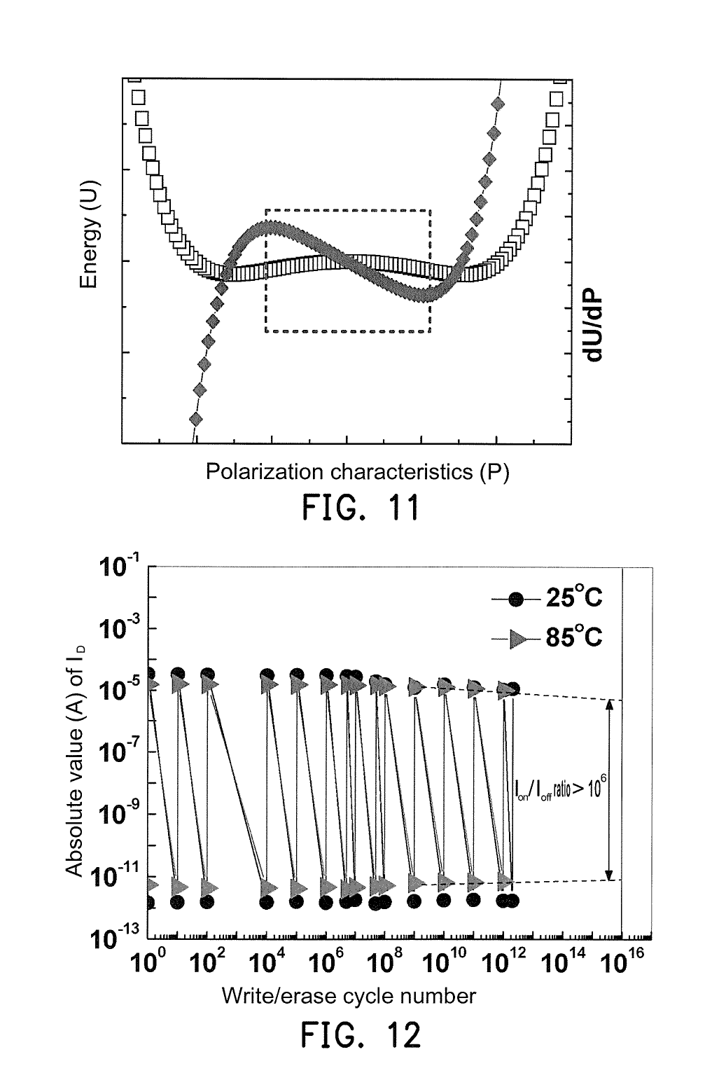

In the following, the semiconductor device characteristics in the above embodiments are described with experimental examples. FIG. 6 is a crystal structure diagram of a ferroelectric material layer of an experimental example of the invention. FIG. 7 is a polarization characteristics diagram of a ferroelectric material layer (HfZrO) of an experimental example of the invention. FIG. 8 is an I_{D}-V_{G} diagram of basic electrical properties of a semiconductor device of an experimental example of the invention. FIG. 9 shows the relationship of subthreshold swing and gate voltage obtained from the I_{D}-V_{G} diagram of FIG. 8. FIG. 10 shows the relationship of surface potential gain and gate voltage obtained from the I_{D}-V_{G} diagram of FIG. 8. FIG. 11 shows the relationship of polarization characteristics (P) and energy (U) and dU/dP obtained from the I_{D}-V_{G} diagram of FIG. 8. FIG. 12 is an endurance test diagram of a semiconductor device of an experimental example of the invention.

In the present experimental example, the semiconductor device has a ferroelectric material layer (HfZrO) and a charge-trapping layer (ZrSiO), and the structure thereof is as shown in FIG. 1. The manufacturing method of the semiconductor device of the present experimental example is as follows. A dry oxide layer used as a buffer layer and having a thickness of 3.5 nm is grown on a silicon substrate, and then a HfZrO layer (21 nm) and a ZrSiO layer (7.5 nm) are deposited in order, and an annealing process is performed at 400° C. Then, a SiO₂ layer used as a tunneling dielectric layer is formed on the ZrSiO layer. Then, a TaN metal layer used as a gate is formed on the SiO₂ layer. Then, a self-aligned BF₂⁺ ion implantation process is performed and activation is performed at a temperature of 950° C. Lastly, an aluminum electrode layer used as a source electrode/drain electrode is formed. Moreover, the linewidth of the present experimental example is 100 μm.

It can be known from FIG. 6 that the ferroelectric material layer (HfZrO) is an orthorhombic crystal, and has ferroelectric polarization characteristics. It can be known from FIG. 7 that, HfO₂ has dielectric characteristics, and ferroelectric-HfZrO has polarization characteristics.

Referring to FIG. 8, a sweep is performed on the semiconductor device of the present experimental example with a bias of +6 V and −6 V, and V_{D} (drain voltage) is −0.2 V. It can be known from the I_{D}-V_{G} diagram of FIG. 8 that, the semiconductor device has lower leakage current (as low as 10⁻¹⁵ A/μm), and has better transistor characteristics. Moreover, the semiconductor device has greater memory operation interval (ΔV_{T} greater than 2 V) and has better memory characteristics. It can be known from FIG. 9 that, the semiconductor device has lower subthreshold swing (54 mv/dec), reaching 60 mv/dec or less, and has better transistor characteristics.

Referring to FIG. 10, a simulation test of surface potential is performed, wherein the surface potential gain of the semiconductor device is greater than 1, thus proving the semiconductor device has a negative capacitance transistor effect. Referring to FIG. 11, a simulation test of energy (U) and polarization characteristics (P) is performed. In FIG. 11, the curve formed by the white box is the relationship curve of energy and polarization characteristics, and the curve formed by the black rhombus is the dU/dP curve obtained after a differential. In the box area in FIG. 11, the dU/dP curve obtained after a differential has a localized negative slope, thus proving the semiconductor device has a negative capacitance transistor effect.

Referring to FIG. 12, an endurance test is performed on the semiconductor device of the experimental example. Under the operating conditions of respectively performing writing and erasing at +4 V and −4 V and a pulse of 20 ns, a stable Iₒₙ/I_{off} ratio greater than 10⁶ can still be measured regardless of whether the 10¹² write/erase (P/E) loops are performed at 25° C. or 85° C. It can therefore be known that, the semiconductor device has good endurance and has better memory characteristics.

Based on the above, the semiconductor devices of the above embodiments at least have the following features. Since the semiconductor devices of the above embodiments adopt both the ferroelectric material layer and the charge-trapping layer, the semiconductor devices can contain both ferroelectric polarization characteristics and a charge-trapping mechanism, and therefore can have better memory characteristics and transistor characteristics.

Lastly, it should be mentioned that: each of the above embodiments is only used to describe the technical solutions of the invention and is not intended to limit the invention; and although the invention is described in detail via each of the above embodiments, those having ordinary skill in the art should understand that: modifications can still be made to the technical solution recited in each of the above embodiments, or portions or all of the technical features thereof can be replaced to achieve the same or similar results; and the modifications or replacements do not result in the departure of the nature of corresponding technical solutions from the scope of the technical solution of each of the embodiments of the invention.

What is claimed is:

1. A semiconductor device, comprising:
a substrate;
a first dielectric layer disposed on the substrate;
a conductive layer disposed on the first dielectric layer; and
a ferroelectric material layer and a charge-trapping layer disposed between the first dielectric layer and the conductive layer by stacking.

2. The semiconductor device of claim 1, wherein the substrate comprises a planar semiconductor substrate or a three-dimensional semiconductor substrate with fin-designed structure.

3. The semiconductor device of claim 2, wherein the substrate comprises a tetravalent semiconductor substrate, a Group III-V semiconductor substrate, or a Group II-VI semiconductor substrate.

4. The semiconductor device of claim 1, wherein a material of the first dielectric layer comprises an oxide.

5. The semiconductor device of claim 1, wherein a material of the conductive layer comprises a metal integrated with a strain function or doped polysilicon.

6. The semiconductor device of claim 5, wherein the strain function of the metal is adjusted by the number of layers of the metal, a compound ratio of the metal or a combination thereof.

7. The semiconductor device of claim 5, wherein the metal comprises Ti, Al, Zr, Hf, V, Ta, Nb, Cr, Mo, W, Co, TiN, TiC, TiAlC, TaC, TaAlC, NbAlC, TiAl, TaAl, TaN, TaCN, WN, TiWN or a combination thereof.

8. The semiconductor device of claim 1, wherein the ferroelectric material layer is disposed between the first dielectric layer and the charge-trapping layer.

9. The semiconductor device of claim 1, wherein the charge-trapping layer is disposed between the first dielectric layer and the ferroelectric material layer.

10. The semiconductor device of claim 1, wherein the ferroelectric material layer has ferroelectric characteristics and anti-ferroelectric characteristics to obtain negative capacitance characteristics.

11. The semiconductor device of claim 1, wherein a material of the ferroelectric material layer comprises hafnium zirconium oxide, hafnium silicon oxide, lead zirconate titanate, barium strontium titanate, strontium bismuth tantalate, lead lanthanum zirconate titanate, hafnium aluminum oxide, hafnium yttrium oxide, LiNbO₃, BaMgF, BaMnF, BaFeF, BaCoF, BaNiF, BaZnF, SrAlF₅, PVDF, PVDF-TrEE, La₁₋ₓSrₓMnO₃ or HfO₂ doped with Sr, Y, Zr, La, Nd, Sm or Gd.

12. The semiconductor device of claim 1, wherein a material of the charge-trapping layer comprises a conductive material, a semiconductor material, a dielectric material, graphene, or a nanodot.

13. The semiconductor device of claim 12, wherein the dielectric material comprises a high-k material, and the high-k material comprises zirconium silicon oxide, silicon nitride, tantalum oxide, silicon oxynitride, barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide, or aluminum oxide.

14. The semiconductor device of claim 12, wherein the nanodot comprises a semiconductor nanodot or a metal nanodot, the semiconductor nanodot comprises a silicon nanodot or a germanium nanodot, and the metal nanodot comprises a gold nanodot or a silver nanodot.

15. The semiconductor device of claim 1, further comprising a second dielectric layer disposed between a composite layer of the ferroelectric material layer and the charge-trapping layer and the conductive layer.

16. The semiconductor device of claim 15, wherein a material of the second dielectric layer comprises an oxide.

17. The semiconductor device of claim 1, further comprising a first doped region and a second doped region respectively disposed in the substrate at one side of and another side of the conductive layer.

18. The semiconductor device of claim 1, wherein the semiconductor device comprises a memory device or a field-effect transistor device.

19. The semiconductor device of claim 18, wherein the memory device comprises a static random access memory, a dynamic random access memory, or a non-volatile memory.

20. A semiconductor device, comprising:
a substrate;
a charge-trapping layer disposed on the substrate;
a first conductive layer disposed on the charge-trapping layer;
a ferroelectric material layer disposed on the first conductive layer; and
a second conductive layer disposed on the ferroelectric material layer.

21. The semiconductor device of claim 20, wherein a ferroelectric capacitor formed by the first conductive layer, the ferroelectric material layer, and the second conductive layer has negative capacitance characteristics.

22. The semiconductor device of claim 20, further comprising a first dielectric layer disposed between the substrate and the charge-trapping layer.

23. The semiconductor device of claim 20, further comprising a second dielectric layer disposed between the first conductive layer and the ferroelectric material layer.

24. The semiconductor device of claim 20, further comprising a first doped region and a second doped region respectively disposed in the substrate at one side of and another side of the first conductive layer.
